(19) United States
(12) Patent Application Publication
(10) Pub. No.: US 2022/0013695 A1
(43) Pub. Date: Jan. 13, 2022

(54) HIGH-STRENGTH LED SUPPORT, LED AND LIGHT-EMITTING DEVICE

(71) Applicant: SHENZHEN JUFEI OPTOELECTRONICS CO., LTD, Shenzhen (CN)

(72) Inventors: Yalan YAO, Guangdong (CN); Zhuangzhi LI, Guangdong (CN); Pei LIU, Guangdong (CN); Zhenliang TAN, Guangdong (CN); Meizheng XING, Guangdong (CN)

(21) Appl. No.: 17/272,474

(22) PCT Filed: Apr. 17, 2019
(86) PCT No.: PCT/CN2019/083112

§ 371 Date: Jul. 22, 2021

(30) Foreign Application Priority Data
Aug. 30, 2018 (CN) 201811005357.3

(51) Int. Cl. H01L 33/48; H01L 33/60; H01L 33/62

(52) U.S. Cl. CPC H01L 33/486; H01L 33/62; H01L 33/60

(57) ABSTRACT

A LED support, an LED and a light-emitting device are provided. The LED support comprising a positive electrode substrate and a negative electrode substrate, an insulating enclosure body enclosing the positive electrode substrate and the negative electrode substrate. A front surface of each of the positive electrode substrate and the negative electrode substrate has a functional region and an enclosure contact region contacting the enclosure body. The functional region and the enclosure contact region of at least one substrate of the positive electrode substrate and the negative electrode substrate are not on the same plane, so that the path between the enclosure contact region and the functional region of the substrate may be extended, that is, the path for the moisture entering the functional region is extended, thereby improving the moisture resistance, reliability and durability of the LED support and the LED manufactured by the LED support.

### CROSS-REFERENCE

This application is a National Phase Patent Application of International Patent Application No. PCT/CN2019/083114, filed on Apr. 17, 2019, which claims priority to Chinese Patent Application No. 201811006329.3, filed Aug. 30, 2018, the entire contents of both of which are incorporated herein by reference in their entirety.

### TECHNICAL FIELD

The invention relates to the LED (Light Emitting Diode) field, particularly related to an LED support and a light-emitting device.

### BACKGROUND

Due to the advantages of rich colors, small sizes, environment-friendly, energy-saving, and long lives, LEDs are widely used in various fields, such as but not limited to daily lighting, outdoor lighting, lighting decoration, advertising signs, automotive lighting, indicators, or traffic lights. Since the LEDs used in various fields are exposed to different external environments, the reliability of LEDs is highly demanded, and the overall strength of LEDs is an important measure of LED reliability.

As shown in FIGS. 1-1 to 1-2, the conventional LED support includes a plastic enclosure 10 forming a reflection cavity, a positive electrode substrate 11, a negative electrode substrate 12 surrounded by the plastic enclosure 10, and a separating region 13 for insulating and isolating the positive electrode substrate 11 and the negative electrode substrate 12. A portion of the front surface of the positive electrode substrate 11 and the negative electrode substrate 12 is in direct contact with the plastic enclosure 10, which serves as an enclosure body contacting region. The other portion located at the bottom of the reflection cavity serves as a functional region. The functional region is for mounting LED chips and other possible electronic components, wiring, die-bonding, and functions as a light-reflecting region. The conventional LED support has the following problems:

The enclosure body contacting region and the functional region on the front surface of the positive electrode substrate 11 and the negative electrode substrate 12 are located on the same plane. Therefore, when the moisture diffuses to the front surface of the substrate along the joint between the side surface of the substrate and the plastic enclosure 10, the moisture easily enters the functional region through the enclosure contacting region on the front surface of the substrate, resulting in a short circuit in the functional region, component damages and even directly leads to LED dysfunction. Besides, since most of the functional regions on the substrates are plated with a metallic silver layer, the metallic silver layer is easily corroded by moisture, causing functional defects. Therefore, the conventional LED support and the LED incorporating such support have a poor moisture resistance.

### SUMMARY

### Technical Problem

The present invention provides an LED support, an LED and a light-emitting device to solve the technical problems and improve the reliability and the moisture resistance of the LED support and the LED manufactured by the LED support.

### Technical Solutions

In order to solve the above technical problem, the present invention provides an LED support, which includes a positive electrode substrate, a negative electrode substrate, and an insulating spacer, wherein the insulating spacer is provided between the positive electrode substrate and the negative electrode substrate to insulate and separate the two. The LED support further includes an insulating enclosure body enclosing the positive electrode substrate, the negative electrode substrate, and the insulating spacer. A functional region and an enclosure contact region contacting the enclosure body are included on a front surface of each of the positive electrode substrate and the negative electrode substrate.

The functional region and the enclosure contact region of at least one of the positive electrode substrate and the negative electrode substrate are not on the same plane.

Optionally, the functional region and the enclosure contact region of the positive electrode substrate are not on the same plane, and the functional region and the enclosure contact region of the negative electrode substrate are not on the same plane, neither.

Optionally, the enclosure contact region is directly connected to the functional region.

Optionally, a connection transition region is further provided between the functional region and the enclosure contact region of at least one of the positive electrode substrate and the negative electrode substrate.

Optionally, the connection transition region is an inclined surface, an arc-shaped surface, or a combined surface, wherein the combined surface includes a combination of at least two of a planar surface, an inclined surface, and an arc-shaped surface.

Optionally, a plane where the functional region is located is higher than a plane where the enclosure contact region is located.

Optionally, a plane where the functional region is located is lower than a plane where the enclosure contact region is located.

Optionally, a height difference between a plane where the functional region is located and a plane where the enclosure contact region is located is greater than zero and less than or equal to a quarter of a depth of a reflection cavity formed by the enclosure body.

Optionally, at least one end of a front surface of the insulating spacer is provided with an insulating protrusion.

Optionally, two opposite ends of the front surface of the insulating spacer are provided with insulating protrusions.

Optionally, the insulating protrusion spans the front surface of the positive electrode substrate and/or the front surface of the negative electrode substrate.

Optionally, the functional regions of the positive electrode substrate and the negative electrode substrate are located at a bottom of the reflection cavity formed by the enclosure body, wherein the insulating protrusion is in direct contact with an inner side surface of the reflection cavity, and a height of the insulating protrusion is less than a height of the inner side surface of the reflection cavity formed by the enclosure body.

Optionally, the insulating protrusion is integrally formed with the insulating spacer, and/or the insulating protrusion and the insulating spacer are made of the same material.

Optionally, a profile of a longitudinal cross-section of the insulating protrusion along a height direction is an arc-shaped profile, or a profile formed by an upper horizontal side, a lower horizontal side, and an arc shape located between the upper horizontal side and the lower horizontal side.

Optionally, two opposite long sides of a lateral cross-section profile of the insulating spacer are arc-shaped sides, or curved sides having at least one curved edge, or bended sides having at least one bended edge, or inclined sides having an included angle greater than or equal to 10° and less than 90° with a short side of the negative electrode substrate.

Optionally, the two opposite long sides of the lateral cross-section profile of the insulating spacer are parallel to each other.

In order to solve the above problem, the present invention further provides an LED, which includes the LED support and at least one LED chip disposed on the positive electrode substrate and/or the negative electrode substrate, wherein a positive electrode lead and a negative electrode lead of the LED chip are electrically connected to the positive electrode substrate and the negative electrode substrate, respectively.

In order to solve the above problem, the present invention further provides a light-emitting device including the LED as described above, wherein the light-emitting device is a lighting device, a light signal indicating device, a supplementary light device, or a backlight device.

### Beneficial Effect

The present invention provides an LED support, an LED and light-emitting device, including a positive electrode substrate, a negative electrode substrate, and an insulating spacer, wherein the insulating spacer is provided between the positive electrode substrate and the negative electrode substrate to insulate and separate the two. The LED support further includes an insulating enclosure body enclosing the positive electrode substrate, the negative electrode substrate, and the insulating spacer. A functional region and an enclosure contact region contacting the enclosure body are included on a front surface of each of the positive electrode substrate and the negative electrode substrate. The functional region and the enclosure contact region of at least one of the positive electrode substrate and the negative electrode substrate are not on the same plane, so that the path between the enclosure contact region and the functional region of the substrate may be extended, that is, the path for the moisture entering the functional region is extended, thereby improving the moisture resistance, reliability and durability of the LED, making the LED more suitable for application scenarios in various environments, and conducive to the promotion and use of the LED.

Further, the insulating spacer between the positive electrode substrate and the negative electrode substrate of the conventional LED support is arranged perpendicular to the long side of the support and in parallel with the positive electrode substrate and the negative electrode substrate. Besides, the insulating spacer is made of a relatively fragile insulating plastic material. Due to its narrow width, there is less plastic material in the insulating spacer and is prone to break, which results in poor overall strength and reliability of the LED support and the LED manufactured by the LED support. To this end, the present invention further provides an insulating protrusion on at least one end of the front surface of the insulating spacer to increase the material amount of the insulating spacer, thereby increasing the overall proportion of the insulating spacer to the support. Therefore, the overall strength of the insulating spacer, the LED support having the insulating spacer, and the LED manufactured by the support can be improved.

### BRIEF DESCRIPTION OF THE DRAWINGS

FIG. 1-1 is a top view of an LED support.

FIG. 1-2 is a cross-sectional view of an LED support shown in FIG. 1-1.

FIG. 2-1 is a top view 1 of an LED support provided in Embodiment 2 of the present invention.

FIG. 2-2 is a top view 2 of an LED support provided in Embodiment 2 of the present invention.

FIG. 2-3 is a top view 3 of an LED support provided in Embodiment 2 of the present invention.

FIG. 2-4 is a top view 4 of an LED support provided in Embodiment 2 of the present invention.

FIG. 2-5 is a top view 5 of an LED support provided in Embodiment 2 of the present invention.

FIG. 2-6 is a top view 6 of an LED support provided in Embodiment 2 of the present invention.

FIG. 2-7 is a top view 7 of an LED support provided in Embodiment 2 of the present invention.

FIG. 2-8 is a top view 8 of an LED support provided in Embodiment 2 of the present invention.

FIG. 3-1 is a top view 1 of an LED support provided in Embodiment 3 of the present invention.

FIG. 3-2 is a top view 2 of an LED support provided in Embodiment 3 of the present invention.

FIG. 3-3 is a top view 3 of an LED support provided in Embodiment 3 of the present invention.

FIG. 3-4 is a top view 4 of an LED support provided in Embodiment 3 of the present invention.

FIG. 3-5 is a top view 5 of an LED support provided in Embodiment 3 of the present invention.

FIG. 3-6 is a top view 6 of an LED support provided in Embodiment 3 of the present invention.

FIG. 4-1 is a top view 7 of an LED support provided in Embodiment 3 of the present invention.

FIG. 4-2 is a top view 8 of an LED support provided in Embodiment 3 of the present invention.

FIG. 4-3 is a top view 9 of an LED support provided in Embodiment 3 of the present invention.

FIG. 4-4 is a top view 10 of an LED support provided in Embodiment 3 of the present invention.

FIG. 5-1 is a top view 1 of an LED support provided in Embodiment 4 of the present invention.

FIG. 5-2 is a top view 2 of an LED support provided in Embodiment 4 of the present invention.

FIG. 5-3 is a top view 3 of an LED support provided in Embodiment 4 of the present invention.

FIG. 5-4 is a top view 4 of an LED support provided in Embodiment 4 of the present invention.

FIG. 6-1 is a top view 5 of an LED support provided in Embodiment 4 of the present invention.

FIG. 6-2 is a top view 6 of an LED support provided in Embodiment 4 of the present invention.

FIG. 6-3 is a top view 7 of an LED support provided in Embodiment 4 of the present invention.

FIG. 6-4 is a top view 8 of an LED support provided in Embodiment 4 of the present invention.

FIG. 7-1 is a cross-sectional view 1 of an LED support provided in Embodiment 5 of the present invention.

FIG. 7-2 is a cross-sectional view 2 of an LED support provided in Embodiment 5 of the present invention.

FIG. 7-3 is a cross-sectional view 3 of an LED support provided in Embodiment 5 of the present invention.

FIG. 7-4 is a cross-sectional view 4 of an LED support provided in Embodiment 5 of the present invention.

FIG. 8-1 is a cross-sectional view 1 of an LED support provided in Embodiment 6 of the present invention.

FIG. 8-2 is a cross-sectional view 2 of an LED support provided in Embodiment 6 of the present invention.

FIG. 8-3 is a cross-sectional view 3 of an LED support provided in Embodiment 6 of the present invention.

FIG. 8-4 is a cross-sectional view 4 of an LED support provided in Embodiment 6 of the present invention.

FIG. 8-5 is a cross-sectional view 5 of an LED support provided in Embodiment 6 of the present invention.

FIG. 8-6 is a cross-sectional view 6 of an LED support provided in Embodiment 6 of the present invention.

FIG. 8-7 is a cross-sectional view 7 of an LED support provided in Embodiment 6 of the present invention.

FIG. 8-8 is a cross-sectional view 8 of an LED support provided in Embodiment 6 of the present invention.

FIG. 9-1 is a cross-sectional view 1 of an LED support provided in Embodiment 7 of the present invention.

FIG. 9-2 is a cross-sectional view 2 of an LED support provided in Embodiment 7 of the present invention.

FIG. 9-3 is a cross-sectional 3 of an LED support provided in Embodiment 7 of the present invention.

FIG. 9-4 is a cross-sectional 4 of an LED support provided in Embodiment 7 of the present invention.

FIG. 9-5 is a cross-sectional view 5 of an LED support provided in Embodiment 7 of the present invention.

FIG. 9-6 is a cross-sectional view 6 of an LED support provided in Embodiment 7 of the present invention.

FIG. 9-7 is a cross-sectional view 7 of an LED support provided in Embodiment 7 of the present invention.

FIG. 9-8 is a cross-sectional view 8 of an LED support provided in Embodiment 7 of the present invention.

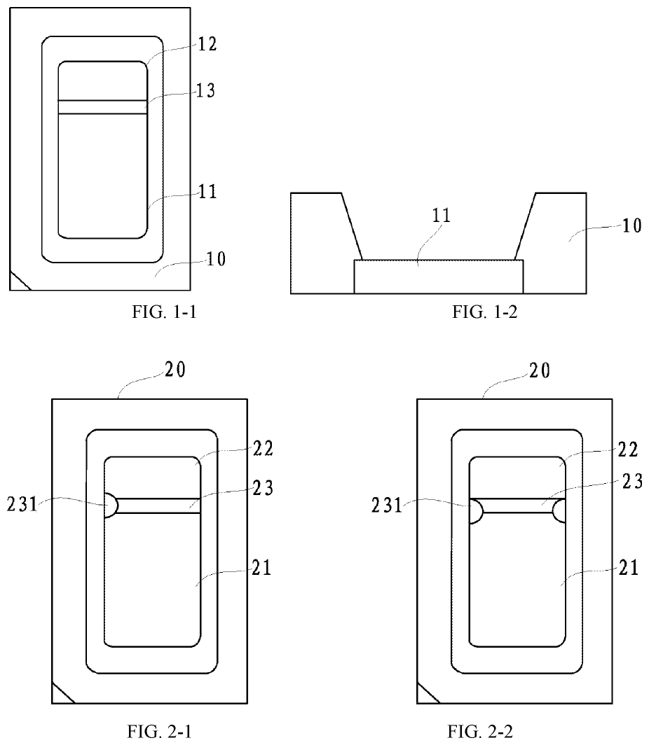

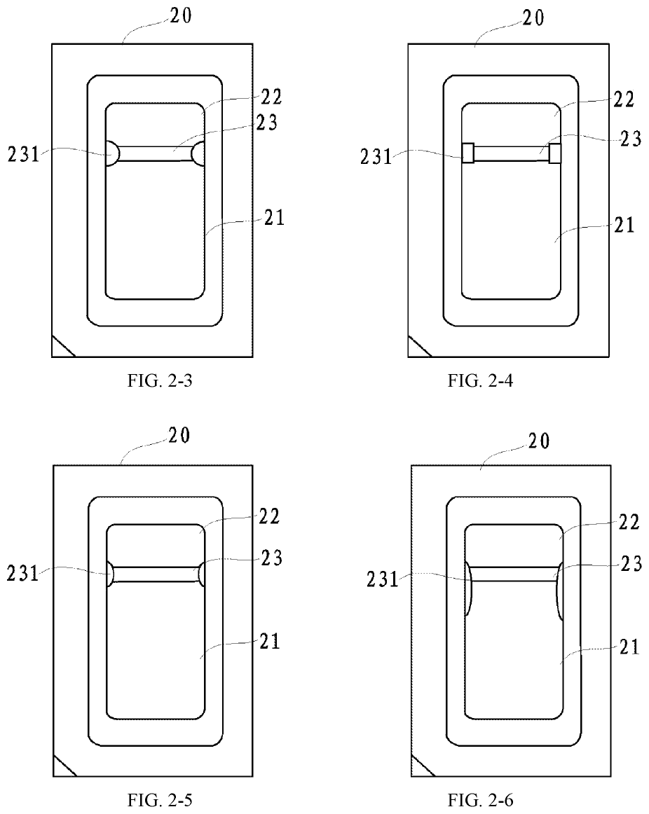

Among them, the reference numeral 10 in FIGS. 1-1 to 1-2 is a plastic enclosure, 11 is a positive electrode substrate, 12 is a negative electrode substrate, and 13 is an insulating spacer. In FIGS. 2-1 to 2-8, 20 is an enclosure body, 21 is a positive electrode substrate, 22 is a negative electrode substrate, 23 is an insulating spacer, and 231 is an insulating protrusion. In FIGS. 3-1 to 3-6, 30 is an enclosure body, 31 is a positive electrode substrate, 32 is a negative electrode substrate, 33 is an insulating separating region. In FIGS. 4-1 to 4-4, 40 is an enclosure body, 41 is a substrate, 41 is a positive electrode substrate, 42 is a negative electrode substrate, and 43 is an insulating separating region. FIGS. 5-1 to 5-4, 50 is an enclosure body, 51 is a positive electrode substrate, 52 is a negative electrode substrate, 53 is an insulating spacer, and 531 is an insulating protrusion. In FIGS. 6-1 to 6-4, 60 is an enclosure body, 61 is a positive electrode substrate, 62 is a negative electrode substrate, 63 is an insulating spacer, and 631 is an insulating protrusion. In FIGS. 7-1 to 7-4, 70 is an enclosure body, 71 is a substrate, 711 is a functional region, 712 is an enclosure contact region, and 731 is an insulating protrusion. In FIG. 8-1 to FIG. 8-8, 80 is an enclosure body, 81 is a substrate, 811 is a functional region, 812 is an enclosure contact region, 813 is a connection transition region, and 831 is an insulating protrusion. In FIG. 9-1 to FIG. 9-8, 90 is an enclosure body, 91 is a substrate, 911 is a functional region, 912 is an enclosure contact region, 913 is a connection transition region, and 931 is an insulating protrusion.

### DETAILED DESCRIPTION OF EMBODIMENTS

In order to make the objectives, technical solutions, and advantages of the present invention clearer, the following further describes the embodiments of the present invention in detail through specific implementations and the accompanying drawings. It should be understood that the specific embodiments described herein are merely to elaborate the embodiments of the present invention, but not to limit the scope of the present invention.

### Embodiment 1

In order to solve the technical problems of poor reliability and poor moisture resistance of the conventional LED support, the present invention provides an LED support that includes an insulating enclosure body enclosing the positive electrode substrate, the negative electrode substrate, and the insulating spacer. A functional region and an enclosure contact region contacting the enclosure body are included on a front surface of each of the positive electrode substrate and the negative electrode substrate, wherein the functional region and the enclosure contact region of at least one of the positive electrode substrate and the negative electrode substrate are not on the same plane, so that the path between the enclosure contact region and the functional region of the substrate may be extended, that is, the path for the moisture entering the functional region is extended, thereby improving the moisture resistance of the LED support and the LED manufactured by the LED support, enhancing the reliability and durability of the LED, making the LED more suitable for application scenarios in various environments, and conducive to the promotion and use of the LED.

In addition, to solve the problem of the poor overall strength of the conventional LED support, the present embodiment provides a high-strength LED support that includes a positive electrode substrate, a negative electrode substrate, and an insulating spacer. A functional region is included on a front surface of each of the positive electrode substrate and the negative electrode substrate. The insulating spacer is provided between the positive electrode substrate and the negative electrode substrate to insulate and separate the two. An insulating protrusion is provided on at least one end of the front surface of the insulating spacer to increase the material amount of the insulating spacer, thereby increasing the overall proportion of the insulating spacer to the support. Therefore, the overall strength and the reliability of the insulating spacer, the LED support having the insulating spacer, and the LED manufactured by the support can be improved.

In one example, the functional regions of the positive electrode substrate and the negative electrode substrate are located at a bottom of a reflection cavity formed by the enclosure body.

The positive electrode substrate and the negative electrode substrate in the present embodiment are both conductive substrates. The conductive substrates may be substrates made of various conductive materials, for example, various metal conductive substrates, including but not limited to, copper substrates, aluminum substrates, iron substrates, silver substrates. The conductive substrates may also be mixed-material conductive substrates containing conductive materials, such as a conductive rubber and the like.

Optionally, in the present embodiment, a reflective layer is provided on the functional region on the front surface of at least one of the positive electrode substrate and the negative electrode substrate to improve the light-emitting efficiency of the support. The reflective layer may be various light reflecting layers capable of improving the light-emitting efficiency, for example, including but not limited to, silver plating.

Optionally, in the present embodiment, a bottom of the enclosure body is exposed on a back surface of at least one of the positive electrode substrate and the negative electrode substrate to serve as an electrode welding region. Alternatively, in some examples, the back surface of at least one of the positive electrode substrate and the negative electrode substrate may not be used as the welding region, but a side surface thereof may be used as the welding region. The specific arrangement may be flexibly adjusted according to specific application requirements.

Optionally, in the present embodiment, the enclosure body may be made of various insulation materials, for example, including but not limited to, various plastics, insulating ceramics, and the like. In one example, materials that may be used for the enclosure body include, but not limited to, epoxide resin (EP), high temperature resistant nylon (PPA plastic material), polyphthalamide (PPA), poly 1,4-cyclohexylene dimethylene terephthalate (PCT), liquid crystal polymer (LCP), sheet molding compound (SMC), epoxy molding compound (EMC), unsaturated polyester (UP) resin, polyethylene terephthalate (PET), polycarbonate (PC), polyhexamethylene adipamide (nylon 66), or glass fiber.

Optionally, the material of the insulating spacer in the present embodiment may be the same as or different from the material of the enclosure body, and the insulating spacer may be formed together with the enclosure body or formed separately.

Further, it should be understood that the method for forming the enclosure body of the present embodiment may be flexibly selected, for example, the enclosure body may be formed by, but not limited to, injection molding.

In one example of the present embodiment, both ends of the front surface of the insulating spacer may be provided with insulating protrusions to further enhance the strength of the insulating spacer. In addition, when insulating protrusions are provided at both ends of the insulating spacer, the shapes, sizes, and materials of the insulating protrusions at both ends may be the same or different as required.

In one example of the present embodiment, the insulating protrusions may span the front surfaces of the positive electrode substrate and/or the front surface of the negative electrode substrate to increase the contact area between the insulating spacer and the positive electrode substrate and/or the negative electrode substrate, and the contact area between the insulating spacer and the inner wall of the enclosure body. This allows the mechanical force received by the insulating spacer to be transmitted to the positive electrode substrate and/or the negative electrode substrate and the enclosure body, thereby further improving the strength of the insulating spacer, and enhancing the overall strength and reliability of the LED support. Meanwhile, the air tightness of the LED support may be increased, thereby improving the moisture resistance of the LED support.

In an example of the present embodiment, the functional regions of the positive electrode substrate and the negative electrode substrate are arranged at a bottom of a reflection cavity formed by the enclosure body. Optionally, the insulating protrusion provided on the insulating spacer is in direct contact with the inner side surface of the reflection cavity, and a height of the insulating protrusion is less than a height of the inner side surface of the reflection cavity, such that the mechanical force received by the insulating spacer is partially transmitted to the enclosure body, thereby further enhancing the strength of the insulating spacer and improving the overall strength and reliability of the LED support. Meanwhile, the air tightness of the LED support may be increased, thereby improving the moisture resistance of the LED support.

It should be understood that, it is also possible to optionally provide an insulating protrusion on the insulating spacer to be in contact with at least one substrate and the enclosure body at the same time, so that the mechanical force received by the insulating spacer is partially transmitted to the enclosure body and at least one substrate to maximize the overall strength, reliability and moisture resistance of the LED support.

In an example of the present embodiment, to further increase the strength of the insulating spacer, the front surface of the insulating spacer may be arranged higher than the front surface of the positive electrode substrate and the negative electrode substrate. The specific height may be flexibly adjusted as required.

In an example of the present embodiment, the insulating protrusions provided on the insulating spacer may be formed integrally with the insulating spacer or formed separately, and may be flexibly adjusted according to a specific manufacturing process and requirements.

In an example of the present embodiment, the material of the insulating protrusions provided on the insulating spacer and the material of the insulating spacer may be the same or may be different in some other examples.

The specific shape and structure of the insulating protrusions in the present embodiment may be flexibly adjusted, for example, the shape of the insulating protrusions may be hemispherical, semicircular, or the like. Alternatively, it may also be less or larger than a hemispherical or semicircular shape. Meanwhile, a profile of a longitudinal cross-section of the insulating protrusion along a height direction may be an arc-shaped profile, or a profile of a longitudinal cross-section of the insulating protrusion along a height direction may be formed by an upper horizontal side, a lower horizontal side, and an arc shape located between the upper horizontal side and the lower horizontal side. Alternatively, the insulating protrusions in the present embodiment may also be arranged as a square shape, other regular shapes, or irregular shapes, and may be flexibly adjusted according to a specific application scenario.

In the present embodiment, at least one end of a front surface of the insulating spacer is provided with an insulating protrusion. The insulating protrusion may be in contact with at least one substrate or the enclosure body to increase the material amount of the insulating spacer and the overall proportion of the insulating spacer to the support. This not only enhances the overall strength of the insulating spacer, but also allows the mechanical force received by the insulating spacer to be partially transmitted to the enclosure body and at least one of the substrates, thereby maximizing the overall strength, reliability and moisture resistance of the LED support, increasing the contact area of the insulating spacer with the substrate and the enclosure body, and improving the air tightness of the LED support.

In the present embodiment, the functional region and the enclosure contact region of at least one of the positive electrode substrate and the negative electrode substrate are not on the same plane. For example, the functional region and the enclosure contact region of the front surface of the positive electrode substrate are not on the same plane, and/or, the functional region and the enclosure contact region of the front surface of the negative electrode substrate are not on the same plane. Specifically, one or two of the functional region and the enclosure contact region of the positive electrode substrate and the negative electrode substrate may be flexibly adjusted according to specific requirements so that they are not on the same plane. For example, in one example, in order to comprehensively improve the sealing performance of the LED support, the functional region and the enclosure contact region of both of the positive electrode substrate and the negative electrode substrate are not on the same plane. This arrangement makes it possible to extend the path between the enclosure contact region and the functional region of the substrate, that is, to extend the path for the moisture entering the functional region, thereby improving the sealing performance of the LED support and the LED manufactured by the LED support, and enhancing the reliability and durability of the LEDs, making the LEDs more suitable for application scenarios in various environments, and conducive to the promotion and use of the LEDs.

In an example of the present embodiment, the enclosure contact region on the front surface of the substrate may be directly connected to the functional region, and the enclosure contact region may be an inclined surface, an arc-shaped surface, or another type of surface.

In another example of the present embodiment, in order to further extend the path between the enclosure contact region and the functional region of the substrate, a connection transition region may also be provided between the enclosure contact region and the functional region of the substrate. In this way, the moisture needs to pass through the enclosure contact region and the connection transition region before it reaches the functional region, which further improves the moisture resistance of the support. In the present embodiment, the connection transition region may also be an inclined surface, an arc-shaped surface, or a combined surface, and the combined surface may also include, but not limited to, a combination of at least two of a planar surface, an inclined surface, and an arc-shaped surface.

In the present embodiment, the functional region and the enclosure contact region of at least one of the positive electrode substrate and the negative electrode substrate of the LED support are arranged to be not on the same plane. Optionally, the plane where the functional region is located may be higher than the plane where the enclosure contact region is located, or the plane where the functional region is located may be lower than the plane where the enclosure contact region is located, so that the path between the enclosure contact region and the functional region of the substrate may be extended, that is, the path for the moisture to reach the functional region is extended, thereby improving the moisture resistance of the LED support and the LED manufactured by the LED support.

### Embodiment 2

In order to facilitate understanding, several examples for arranging the insulating protrusions on the insulating spacer are described below in the present embodiment.

Referring to FIG. 2-1, 20 is the enclosure body, 21 is the positive electrode substrate, 22 is the negative electrode substrate, 23 is the insulating spacer, and 231 is the insulating protrusion. In the LED support shown in FIG. 2-1, the insulating protrusion 231 is provided at the left end of the insulating spacer 23. The insulating protrusion 231 may be a hemispherical shape or a semicircular shape. In addition, the insulating protrusion 231 spans the positive electrode substrate and the negative electrode substrate and may optionally be in contact with the enclosure body 20 at the same time. In one example, the insulating protrusion 231, the insulating spacer 23 and the enclosure body 20 may be formed by the same manufacturing process, or formed by different manufacturing processes, and in one example, the three may be integrally formed, for example, integrally formed by injection molding. The insulating protrusion 231 is in contact with the positive electrode substrate 21, the negative electrode substrate 22, and the enclosure body 20 at the same time, so that the mechanical force received by the insulating spacer is partially transmitted to the enclosure body and at least one substrate, thereby maximizing the overall strength, the reliability and moisture resistance of the LED support, and increasing the contact area with the substrate and the enclosure body 20 to improve the air tightness of the LED support.

It should be understood that, in some embodiments, the insulating protrusions 231 may be arranged on only one of the substrates. For example, as shown in FIG. 2-2, the insulating protrusions 231 are provided at both ends of the insulating spacer 23, and the shape and size of the insulating protrusions 231 may be the same or different as required. The insulating protrusion 231 is only provided on the positive electrode substrate 21. Alternatively, it is also possible to provide the insulating protrusion 231 of one end on the positive electrode substrate 21, and the insulating protrusion 231 of the other end on the negative electrode substrate 22. The insulating protrusion 231 may be in contact with the enclosure body 20 at the same time, so that the mechanical force received by the insulating spacer is partially transmitted to the enclosure body and the positive electrode substrate to improve the overall strength, reliability, and moisture resistance of the LED support. Further, the contact area with the substrate and the enclosure body 20 is increased to improve the air tightness of the LED support.

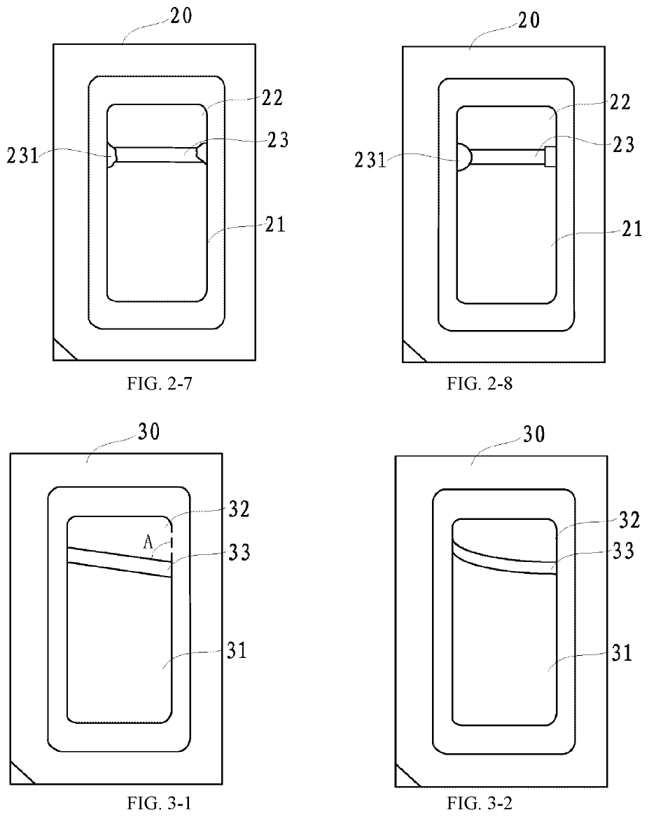

Referring to FIG. 2-3 for another example, compared with the LED support shown in FIG. 2-2, the difference is that both ends of the insulating spacer 23 are provided with insulating protrusions 231. The shape and the size of the insulating protrusions 231 are the same, and the insulating protrusions 231 span the positive electrode substrate 21 and the negative electrode substrate 22. The insulating protrusions 231 may be in contact with the enclosure body 20 at the same time, so that the mechanical force received by the insulating spacer is partially transmitted to the enclosure body, the positive electrode substrate, and the negative electrode substrate, thereby improving the overall strength, reliability, and moisture resistance of the LED support. Further, the contact area with the positive electrode substrate 21, the negative electrode substrate 22, and the enclosure body 20 is increased to improve the air tightness of the LED support.

Referring to FIG. 2-4 for another example, compared with the LED support shown in FIG. 2-3, the difference is that both ends of the insulating spacer 23 are provided with insulating protrusions 231, and the lateral cross-section of the insulating protrusions 231 are both rectangular protrusion structures. The insulating protrusions 231 span the positive electrode substrate 21 and the negative electrode substrate 22. The insulating protrusions 231 may be in contact with the enclosure body 20 at the same time, so that the mechanical force received by the insulating spacer is partially transmitted to the enclosure body, the positive electrode substrate, and the negative electrode substrate, thereby improving the overall strength, reliability, and moisture resistance of the LED support.

Referring to FIG. 2-5 for another example, compared with the LED support shown in FIG. 2-3, the difference is that both ends of the insulating spacer 23 are provided with insulating protrusions 231, and the lateral cross-section of the insulating protrusions 231 are both non-semicircular arc-shaped surfaces. The insulating protrusions 231 also span the positive electrode substrate 21 and the negative electrode substrate 22. The insulating protrusions 231 may be in contact with the enclosure body 20 at the same time, so that the mechanical force received by the insulating spacer is partially transmitted to the enclosure body, the positive electrode substrate, and the negative electrode substrate, thereby improving the overall strength, reliability, and moisture resistance of the LED support. In addition, it should be understood that in the present embodiment, on the premise that the light-emitting efficiency of the LED support is satisfied, the height, width, and length of the insulating protrusion may be extended as much as possible to further improve the strength and moisture resistance. Taking FIG. 2-6 as an example, the insulating protrusion 231 extends as much as possible along the positive electrode substrate 21 in a longitudinal direction to increase the contact area of the insulating protrusion with the enclosure body 20 and the substrate.

In other examples of the present embodiment, the insulating protrusion 231 may be an irregular shape. For example, one of the exemplary insulating protrusions 231 are irregularly shaped protrusions, that also span the positive electrode substrate 21 and the negative electrode substrate 22. The insulating protrusion 231 may be in contact with the enclosure body 20 at the same time, so that the mechanical force received by the insulating spacer is partially transmitted to the enclosure body, the positive electrode substrate, and the negative electrode substrate, thereby improving the overall strength, reliability and moisture resistance of the LED support.

In other examples of the present embodiment, the insulating protrusions 231 are provided at both ends of the insulating spacer 23, and the shapes and sizes of the insulating protrusions 231 at both ends may also be different. For example, referring to FIG. 2-8, the insulating protrusion 231 provided at the left end of the insulating spacer is a hemispherical or semicircular shape, while the insulating protrusion provided at the right end of the insulating spacer is a hexahedron shape.

In the present embodiment, the insulating protrusion provided on at least one end of the front surface of the insulating spacer may be in contact with at least one substrate or enclosure body at the same time, which increases the overall proportion of the insulating spacer to the support and enhances the overall strength of the insulating spacer. In addition, this allows the mechanical force received by the insulating spacer to be partially transmitted to the enclosure body and at least one of the substrates, thereby maximizing the overall strength, reliability, and moisture resistance of the LED support.

### Embodiment 3

As shown in FIGS. 1-1 to 1-2, the insulating spacer between the positive electrode substrate and the negative electrode substrate of the conventional LED support is arranged perpendicular to the long side of the support and in parallel with the positive electrode substrate and the negative electrode substrate. Besides, the insulating spacer is made of a relatively fragile insulating plastic material. Due to its narrow width, there is less plastic material in the insulating spacer and is prone to break, which results in poor overall strength and reliability of the LED support.

To this end, the present invention further provides an LED support with a new structure, wherein two opposite long sides of a lateral cross-section profile of the insulating spacer of the LED support are arc-shaped sides, or curved sides having at least one curved edge, or bended sides having at least one bended edge, or inclined sides having an included angle greater than or equal to 10° and less than 90° with a short side of the negative electrode substrate. This allows the mechanical force received by the insulating spacer to be partially transmitted to the positive electrode substrate, the negative electrode substrate, and the enclosure body, thereby improving the strength of the insulating spacer.

Optionally, in the present embodiment, the two opposite long sides of the lateral cross-section profile of the insulating spacer may be arranged parallel or non-parallel to each other, which can be flexibly adjusted as required. To facilitate understanding, the following embodiment will describe two examples of parallel configuration and non-parallel configuration.

Example of Parallel Configuration:

Referring to FIG. 3-1, 30 is an enclosure body, 31 is a positive electrode substrate, 32 is a negative electrode substrate, and 33 is an insulating separating region. In FIG. 3-1, the dashed line represents the short side of the negative electrode substrate 32. As shown in FIG. 3-1, the two opposite long sides of a lateral cross-section profile of the insulating spacer 33 are inclined sides having an included angle greater than or equal to 10° and less than 90° with a short side of the negative electrode substrate, that is, the included angle A in FIG. 3-1 is greater than or equal to 10° and less than 90°. The value of the included angle can be flexibly adjusted according to at least one of the following factors: the strength requirements of the specific application scenario, the material chosen for the insulating spacer, and the manufacturing process. In one example, the value of the included angle A may be from 75° to 85°, the specific values may be, such as 75 °, 78 °, 80 °, 83 °, 85°, and so on. This allows the mechanical force received by the insulating spacer 33 to be partially transmitted to the positive electrode substrate 31, the negative electrode substrate 32, and the enclosure body 30, thereby improving the strength of the insulating spacer 33, and enhancing the overall strength and reliability of the LED support.

In the present embodiment, in addition to the inclined sides, the two opposite long sides of a lateral cross-section profile of the insulating spacer 33 may be the arc-shaped sides. Referring to FIG. 3-2 for an exemplary arrangement, the two opposite long sides of a lateral cross-section profile of the insulating spacer 33 are two arc-shaped sides that are parallel to each other. The arrangement of the arc-shaped sides allows the mechanical force received by the insulating spacer 33 to be partially transmitted to the positive electrode substrate 31, the negative electrode substrate 32, and the enclosure body 30, thereby improving the strength of the insulating spacer 33.

In the present embodiment, in addition to the inclined sides and the arc-shaped sides, the two opposite long sides of a lateral cross-section profile of the insulating spacer 33 may be the curved sides. Referring to FIG. 3-3 for an exemplary arrangement, the two opposite long sides of a lateral cross-section profile of the insulating spacer 33 are two curved sides that are parallel to each other. The arrangement of the curved sides allows the mechanical force received by the insulating spacer 33 to be partially transmitted to the positive electrode substrate 31, the negative electrode substrate 32, and the enclosure body 30, thereby improving the strength of the insulating spacer 33. In the present embodiment, the number of curved edges of the curved sides may be flexibly adjusted. For example, it may be arranged as the curved sides shown in FIG. 3-3, or the curved sides shown in FIG. 3-5. Alternatively, it may also be other forms of curved sides.

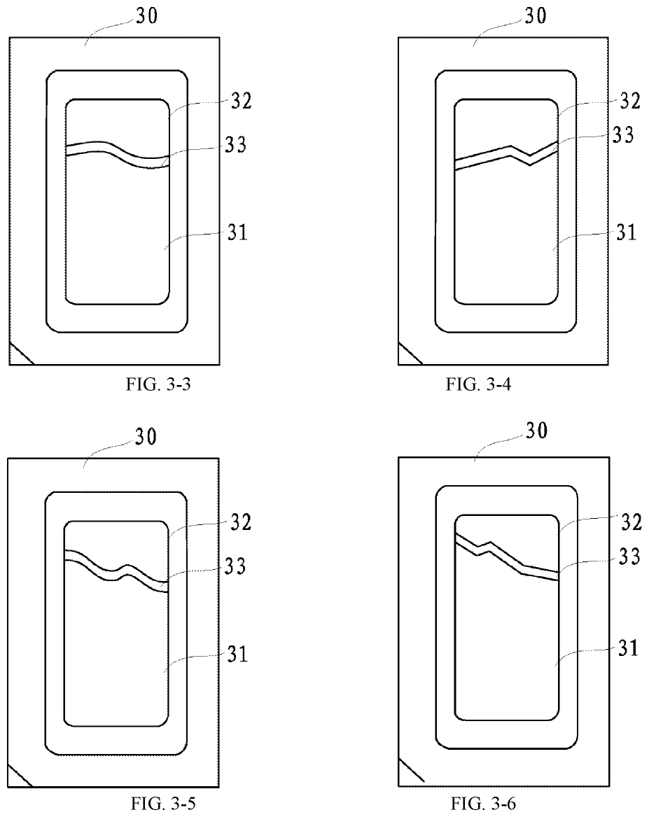

In the present embodiment, in addition to the inclined sides, the arc-shaped sides, and the curved sides, the two opposite long sides of a lateral cross-section profile of the insulating spacer 33 may be the bended sides having at least one bended edge. Referring to FIG. 3-4 for an exemplary arrangement, the two opposite long sides of a lateral cross-section profile of the insulating spacer 33 are two bended sides that are parallel to each other. The arrangement of the bended sides allows the mechanical force received by the insulating spacer 33 to be partially transmitted to the positive electrode substrate 31, the negative electrode substrate 32, and the enclosure body 30, thereby improving the strength of the insulating spacer 33. In the present embodiment, the number of bended edges of the bended sides may be flexibly adjusted. For example, it may be arranged as the bended sides shown in FIG. 3-4, or the bended sides shown in FIG. 3-6. Alternatively, it may be other forms of bended sides.

Example of Non-Parallel Configuration:

Referring to FIG. 4-1, 40 is an enclosure body, 41 is a positive electrode substrate, 42 is a negative electrode substrate, and 43 is an insulating separating region. As shown in FIG. 4-1, the two opposite long sides of a lateral cross-section profile of the insulating spacer 43 are inclined sides having an included angle greater than or equal to 10° and less than 90° with a short side of the negative electrode substrate. The two inclined sides are non-parallel to each other, such that the mechanical force received by the insulating spacer 43 to be partially transmitted to the positive electrode substrate 41, the negative electrode substrate 42, and the enclosure body 40, thereby improving the strength of the insulating spacer 43, and enhancing the overall strength and reliability of the LED support.

In the present embodiment, in addition to the inclined sides, the two opposite long sides of a lateral cross-section profile of the insulating spacer 43 may be arc-shaped sides. Referring to FIG. 4-2 for an exemplary arrangement, the two opposite long sides of a lateral cross-section profile of the insulating spacer 43 are two arc-shaped sides that are non-parallel to each other. The arrangement of the non-parallel arc-shaped sides also allows the mechanical force received by the insulating spacer 43 to be partially transmitted to the positive electrode substrate 41, the negative electrode substrate 42, and the enclosure body 40, thereby improving the strength of the insulating spacer 43.

In the present embodiment, in addition to the inclined sides and the arc-shaped sides, the two opposite long sides of a lateral cross-section profile of the insulating spacer 43 may be curved sides. Referring to FIG. 4-3 for an exemplary arrangement, the two opposite long sides of a lateral cross-section profile of the insulating spacer 43 are two curved sides that are non-parallel to each other. The arrangement of the non-parallel curved sides allows the mechanical force received by the insulating spacer 43 to be partially transmitted to the positive electrode substrate 41, the negative electrode substrate 42, and the enclosure body 40, thereby improving the strength of the insulating spacer 43.

In the present embodiment, in addition to the inclined sides, the arc-shaped sides, and the curved sides, the two opposite long sides of a lateral cross-section profile of the insulating spacer 43 may be bended sides having at least one bended edge. Referring to FIG. 4-4 for an exemplary arrangement, the two opposite long sides of a lateral cross-section profile of the insulating spacer 43 are two bended sides that are non-parallel to each other. The arrangement of the non-parallel bended sides allows the mechanical force received by the insulating spacer 43 to be partially transmitted to the positive electrode substrate 41, the negative electrode substrate 42, and the enclosure body 40, thereby improving the strength of the insulating spacer 43.

In the present embodiment, the two opposite long sides of a lateral cross-section profile of the insulating spacer are arranged as the arc-shaped sides, the curved sides, the bended sides, or the inclined sides having an included angle greater than or equal to 10° and less than 90° with a short side of the negative electrode substrate. This allows the mechanical force received by the insulating spacer to be partially transmitted to the positive electrode substrate and/or the negative electrode substrate, thereby improving the strength of the insulating spacer and enhancing the overall strength and reliability of the LED support and the LED manufactured by the LED support.

### Embodiment 4

It should be understood that, in the present embodiment, the insulation spacer in Embodiment 3 may also be combined with the insulating protrusion structure in Embodiment 1 or Embodiment 2 to double the strength of the insulation spacer, thereby improving the overall strength of the LED support and increasing the contact area of the insulating spacer with the substrate and/or the enclosure body at the same time to improve the moisture resistance of the LED support. To facilitate understanding, two examples of the present embodiment describe the combination of the insulating protrusions and insulating spacers that are arranged in parallel and non-parallel configuration, respectively.

Example of Parallel Configuration and Insulating Protrusion:

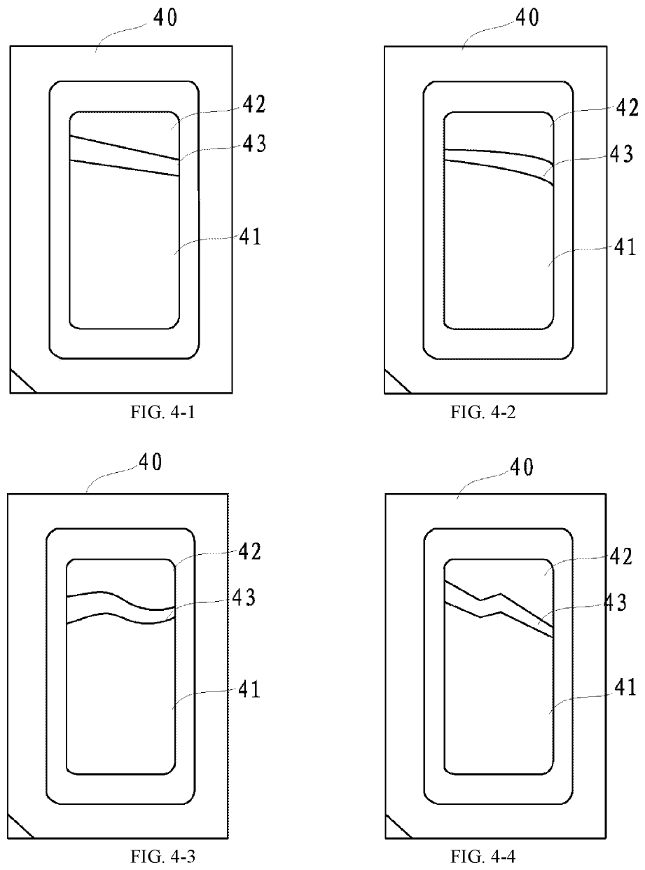

Referring to FIG. 5-1, 50 is an enclosure body, 51 is a positive electrode substrate, 52 is a negative electrode substrate, 53 is an insulating separating region, and 531 is an insulating protrusion. In FIG. 5-1, two opposite long sides of a lateral cross-section profile of the insulating spacer 53 are two parallel inclined sides having an included angle greater than 0° and less than or equal to 45° with the horizontal line on the front surface of the positive electrode substrate. This allows the mechanical force received by the insulating spacer 53 to be partially transmitted to the positive electrode substrate 51, the negative electrode substrate 52, and the enclosure body 50, thereby improving the strength of the insulating spacer 53, and enhancing the overall strength and reliability of the LED support. Meanwhile, the insulating protrusions 531 are provided at both ends of the insulating spacer 53, and the insulating protrusions 531 span the positive electrode substrate 51 and the negative electrode substrate 52. Optionally, the insulating protrusions 531 may be in contact with the enclosure body 50 at the same time, so that the mechanical force received by the insulating spacer 53 may be partially transmitted to the enclosure body 50, the positive electrode substrate 51, and the negative electrode substrate 52, which further improves the overall strength, reliability, and moisture resistance of the LED support, and increases the contact area with the substrate and/or the enclosure body 50, thereby enhancing the air tightness of the LED support.

In the present embodiment, in addition to the inclined sides, the two opposite long sides of a lateral cross-section profile of the insulating spacer 53 may be arc-shaped sides. Referring to FIG. 5-2 for an exemplary arrangement, the two opposite long sides of a lateral cross-section profile of the insulating spacer 53 are two arc-shaped sides that are parallel to each other. The arrangement of the arc-shaped sides also allows the mechanical force received by the insulating spacer 53 to be partially transmitted to the positive electrode substrate 51, the negative electrode substrate 52, and the enclosure body 50, thereby improving the strength of the insulating spacer 53. Meanwhile, the insulating protrusions 531 are also provided at both ends of the insulating spacer 53, and the insulating protrusions 531 span the positive electrode substrate 51 and negative electrode substrate 52. Optionally, the insulating protrusions 531 are in contact with the enclosure body 50, so that mechanical force received by the insulating spacer 53 may be partially transmitted to the enclosure body 50, the positive electrode substrate 51 and the negative electrode substrate 52, which further improves the overall strength, reliability, and moisture resistance of the LED support, and also increases the contact area with the substrate and the enclosure body 50, thereby enhancing the air tightness of the LED support.

In the present embodiment, in addition to the inclined sides and the arc-shaped sides, the two opposite long sides of a lateral cross-section profile of the insulating spacer 53 may be the curved sides. Referring to FIG. 5-3 for an exemplary arrangement, the two opposite long sides of a lateral cross-section profile of the insulating spacer 53 are two curved sides that are parallel to each other. The arrangement of the curved sides allows the mechanical force received by the insulating spacer 53 to be partially transmitted to the positive electrode substrate 51, the negative electrode substrate 52, and the enclosure body 50, thereby improving the strength of the insulating spacer 53. Meanwhile, the insulating protrusions 531 are provided at both ends of the insulating spacer 53, and the insulating protrusions 531 span the positive electrode substrate 51 and the negative electrode substrate 52. The insulating protrusions 531 are in contact with the enclosure body 50, so that the mechanical force received by the insulating spacer 53 is partially transmitted to the enclosure body 50, the positive electrode substrate 51, and the negative electrode substrate 52, which further improves the overall strength, reliability, and moisture resistance of the LED support.

In the present embodiment, in addition to the inclined sides, the arc-shaped sides, and the curved sides, the two opposite long sides of a lateral cross-section profile of the insulating spacer 53 may be the bended sides having at least one bended edge. Referring to FIG. 5-4 for an exemplary arrangement, the two opposite long sides of a lateral cross-section profile of the insulating spacer 53 are two bended sides that are parallel to each other. The arrangement of the bended sides allows the mechanical force received by the insulating spacer 53 to be partially transmitted to the positive electrode substrate 51, the negative electrode substrate 52, and the enclosure body 50, thereby improving the strength of the insulating spacer 53. Meanwhile, the insulating protrusions 531 are also provided at both ends of the insulating spacer 53, and the insulating protrusions 531 span the positive electrode substrate 51 and the negative electrode substrate 52. The insulating protrusions 531 are in contact with the enclosure body 50, so that the mechanical force received by the insulating spacer 53 is partially transmitted to the enclosure body 50, the positive electrode substrate 51, and the negative electrode substrate 52, which further improves the overall strength, reliability, and moisture resistance of the LED support, and also increases the contact area of the insulating spacer with the substrate and the enclosure body 50, thereby enhancing the air tightness of the LED support.

Example of Non-Parallel Configuration:

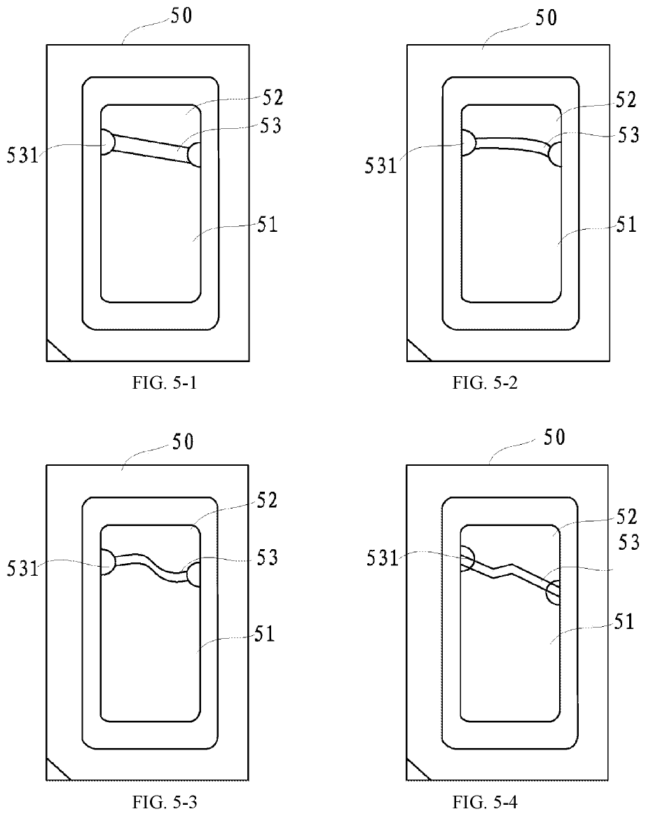

Referring to FIG. 6-1, 60 is an enclosure body, 61 is a positive electrode substrate, 62 is a negative electrode substrate, 63 is an insulating separating region, and 631 is an insulating protrusion. In FIG. 6-1, two opposite long sides of a lateral cross-section profile of the insulating spacer 63 are two inclined sides having an included angle greater than 0° and less than or equal to 45° with the horizontal line on the front surface of the positive electrode substrate. The two inclined sides are not parallel to each other. This allows the mechanical force received by the insulating spacer 63 to be partially transmitted to the positive electrode substrate 61 and the negative electrode substrate 62, thereby improving the strength of the insulating spacer 63, and enhancing the overall strength and reliability of the LED support. Meanwhile, the insulating protrusions 631 are provided at both ends of the insulating spacer 63, and the insulating protrusions 631 span the positive electrode substrate 61 and the negative electrode substrate 62. The insulating protrusions 631 are in contact with the enclosure body 60, so that the mechanical force received by the insulating spacer 63 is partially transmitted to the enclosure body 60, the positive electrode substrate 61, and the negative electrode substrate 62, which further improves the overall strength, reliability, and moisture resistance of the LED support, and increases the contact area with the substrate and the enclosure body 60, thereby enhancing the air tightness of the LED support.

In the present embodiment, in addition to the inclined sides, the two opposite long sides of a lateral cross-section profile of the insulating spacer 63 may be the arc-shaped sides. Referring to FIG. 6-2 for an exemplary arrangement, the two opposite long sides of a lateral cross-section profile of the insulating spacer 63 are two arc-shaped sides that are non-parallel to each other. The arrangement of the non-parallel arc-shaped sides also allows the mechanical force received by the insulating spacer 63 to be partially transmitted to the positive electrode substrate 61, and the negative electrode substrate 62, thereby improving the strength of the insulating spacer 63. Meanwhile, the insulating protrusions 631 are also provided at both ends of the insulating spacer 63, and the insulating protrusions 631 span the positive electrode substrate 61 and negative electrode substrate 62. The insulating protrusions 631 are in contact with the enclosure body 60, so that mechanical force received by the insulating spacer 63 may be partially transmitted to the enclosure body 60, the positive electrode substrate 61 and the negative electrode substrate 62, which further improves the overall strength, reliability, and moisture resistance of the LED support, and also increases the contact area with the substrate and the enclosure body 60, thereby enhancing the air tightness of the LED support.

In the present embodiment, in addition to the inclined sides and the arc-shaped sides, the two opposite long sides of a lateral cross-section profile of the insulating spacer 63 may be the curved sides. Referring to FIG. 6-3 for an exemplary arrangement, the two opposite long sides of a lateral cross-section profile of the insulating spacer 63 are two curved sides that are non-parallel to each other. The arrangement of the non-parallel curved sides allows the mechanical force received by the insulating spacer 63 to be partially transmitted to the positive electrode substrate 61, and the negative electrode substrate 62, thereby improving the strength of the insulating spacer 63. Meanwhile, the insulating protrusions 631 are provided at both ends of the insulating spacer 63, and the insulating protrusions 631 span the positive electrode substrate 61 and the negative electrode substrate 62. The insulating protrusions 631 are in contact with the enclosure body 60, so that the mechanical force received by the insulating spacer 63 is partially transmitted to the enclosure body 60, the positive electrode substrate 61, and the negative electrode substrate 62, which further improves the overall strength, reliability, and moisture resistance of the LED support, and increases the contact area with the substrate and the enclosure body 60, thereby enhancing the air tightness of the LED support.

In the present embodiment, in addition to the inclined sides, the arc-shaped sides, and the curved sides, the two opposite long sides of a lateral cross-section profile of the insulating spacer 63 may be bended sides having at least one bended edge. Referring to FIG. 6-4 for an exemplary arrangement, the two opposite long sides of a lateral cross-section profile of the insulating spacer 63 are two bended sides that are non-parallel to each other. The arrangement of the bended sides allows the mechanical force received by the insulating spacer 63 to be partially transmitted to the positive electrode substrate 61, and the negative electrode substrate 62, thereby improving the strength of the insulating spacer 63. Meanwhile, the insulating protrusions 631 are provided at both ends of the insulating spacer 63, and the insulating protrusions 631 span the positive electrode substrate 61 and the negative electrode substrate 62. The insulating protrusions 631 are in contact with the enclosure body 60, so that the mechanical force received by the insulating spacer 63 is partially transmitted to the enclosure body 60, the positive electrode substrate 61, and the negative electrode substrate 62, which further improves the overall strength, reliability, and moisture resistance of the LED support, and also increases the contact area with the substrate and the enclosure body 60, thereby enhancing the air tightness of the LED support.

In the present embodiment, the two opposite long sides of a lateral cross-section profile of the insulating spacer are arranged as the arc-shaped sides, the curved sides, the bended sides, or the inclined sides having an included angle greater than 0° and less than 64° with the horizontal line on the front surface of the positive electrode substrate. Meanwhile, the insulating protrusions are provided at both ends of the insulating spacer, and the insulating protrusions span the positive electrode substrate and the negative electrode substrate. The insulating protrusions are in contact with the enclosure body, so that the mechanical force received by the insulating spacer is partially transmitted to the enclosure body, the positive electrode substrate, and the negative electrode substrate, which further improves the overall strength, reliability, and moisture resistance of the LED support, and increases the contact area with the substrate and the enclosure body, thereby enhancing the air tightness of the LED support.

### Embodiment 5

In order to facilitate understanding, the present embodiment shows an example in which the enclosure contact region on the substrate is directly connected to the functional region, and the functional region is located above the enclosure contact region.

In FIG. 7-1 to FIG. 7-4, 70 is an enclosure body, 71 is a substrate (it may be a positive electrode substrate and/or a negative electrode substrate), 711 is a functional region, 712 is an enclosure contact region, and 731 are insulating protrusions provided at both ends of an insulating spacer. It should be understood that the specific arrangement of the insulating protrusions may be referred to the foregoing embodiments and is not limited to the present embodiment.

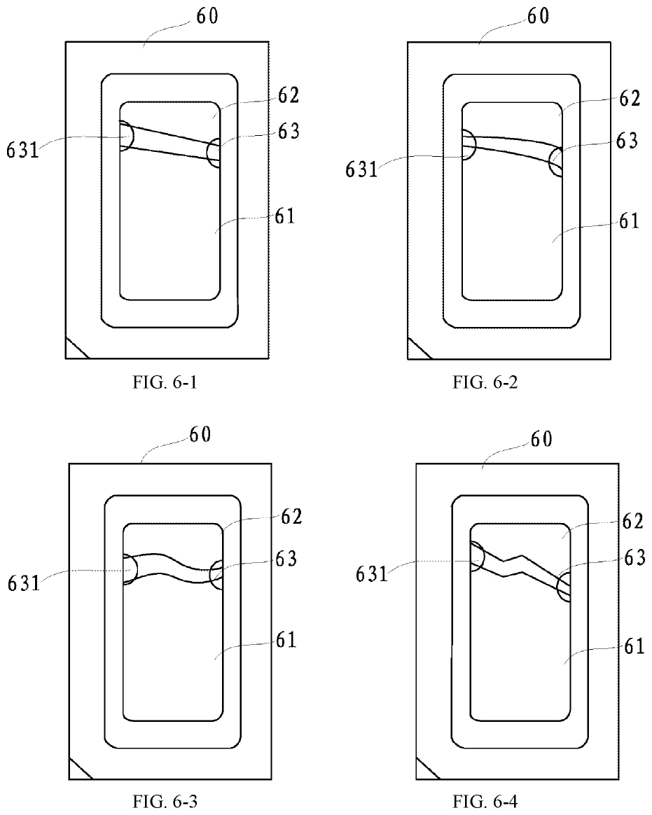

Referring to FIG. 7-1, a schematic diagram of a direct connection between an enclosure contact region and a functional region on a substrate is depicted. As shown in FIG. 7-1, the enclosure contact region 712 is an inclined surface, and the functional region 711 is a planar surface located at the enclosure contact region 712. Alternatively, the functional region 711 may be provided as a non-planar surface. Compared with the conventional art where the enclosure contact region and the functional region are on the same plane, in the present embodiment, the path between the enclosure contact region 712 and the functional region 711 is significantly extended, so that the path for the moisture entering the functional region can be lengthened, thereby improving the moisture resistance of the support, and further enhancing the reliability of the LED lamp or other products manufactured by the support.

In some examples, the enclosure contact region 712 may not be an inclined surface but other types of surfaces. For example, as shown in FIG. 7-2, the enclosure contact region 712 is an arc-shaped surface, and the arc-shaped surface is a convex arc-shaped surface protruding outward from the substrate 71. Compared with the inclined surface in FIG. 7-1, the arrangement of the convex arc-shaped surface in FIG. 7-2 can further extend the path for the moisture to enter the functional region, and thus further improves the moisture resistance.

In some examples, when the enclosure contact region 712 is a curved surface, in addition to the convex curved surface shown in FIG. 7-2, it can be other types of curved surfaces. For example, FIG. 7-3 shows a concave curved surface that is curved toward the inside of the substrate 71. Compared with the inclined surface shown in FIG. 7-1, the path for the moisture entering the functional region can be further extended, so that the moisture resistance can be further improved.

Moreover, it should be understood that, in the present embodiment, in addition to the inclined surface or the arc-shaped surface, the enclosure contact region 712 may be provided as other types of surfaces as required, and it may be a regular surface or an irregular surface. For example, as shown in FIG. 7-4, the enclosure contact region 712 is a curved surface. Compared with the inclined surface shown in FIG. 7-1, the path for the moisture entering the functional region can be further extended, so that the moisture resistance can be further improved.

In addition, it should be understood that the enclosure contact regions 712 on opposite sides in FIGS. 7-1 to 7-4 may be provided on the same plane or different plane, and can be flexibly adjusted according to the application scenario.

In some examples, the manufacturing process of the above-mentioned enclosure contact region 712 may be flexibly selected, such as, but not limited to, etching and cutting. The manufacturing method is simple, low cost, and high efficiency, which can improve the moisture resistance of the LED support while ensuring the production cost and the efficiency of the support.

### Embodiment 6

In order to facilitate understanding, the present embodiment shows an example in which a connection transition region is provided between the enclosure contact region and the functional region on the substrate, and the functional region is located above the enclosure contact region.

Optionally, in the present embodiment, a plane where the functional region is located is higher than a plane where the enclosure contact region is located, and the specific height difference between the two may be flexibly adjusted according to the application scenario. For example, a height difference between a plane where the functional region is located and a plane where the enclosure contact region is located may be set to be greater than zero and less than or equal to a quarter of a depth of a reflection cavity. Alternatively, the height difference may also be set to be other values as required, such as greater than zero and less than or equal to one-fifth, one-sixth, or one-third of the depth of the reflection cavity.

Optionally, in the present embodiment, the connection transition region between the enclosure contact region and the functional region may also be at least partially in contact with the enclosure body, so that the contact area between the substrate and the enclosure body may be increased, the strength of the support may be improved, and the path for the moisture entering the functional region may be further extended.

In the present embodiment, the enclosure contact region and the connection transition region may be provided on the same plane or different plane, and the types of the two may be the same or different. It should also be understood that the enclosure contact region in the present embodiment may also be several types of surfaces as shown in Embodiment 2.

In FIG. 8-1 to FIG. 8-8, 80 is an enclosure body, 81 is a substrate (it may be a positive electrode substrate and/or a negative electrode substrate), 811 is a functional region, 812 is an enclosure contact region, and 831 are insulating protrusions provided at both ends of an insulating spacer. It should be understood that the specific arrangement of the insulating protrusions can refer to the foregoing embodiments and is not limited to the present embodiment.

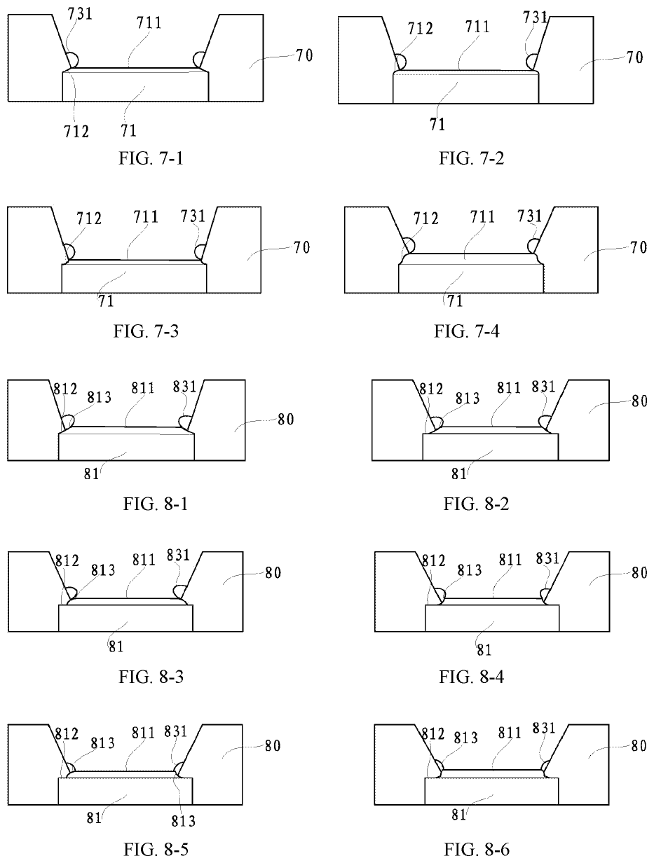

Referring to FIG. 8-1 for an example, the enclosure contact region 812 is an inclined surface area where the front surface of the substrate is in direct contact with the enclosure body 80, and the connection transition region 813 is an inclined surface area where the front surface of the substrate is not in contact with the enclosure body 80. The connection transition region 813 and the enclosure contact region 812 form an inclined surface, that is, they are located on the same plane. Through the arrangement of the connection transition region 813, the path between the enclosure contact region 812 and the functional region 811 may be further extended, and the moisture resistance of the support may be improved.

Referring to FIG. 8-2 for another example, the enclosure contact region 812 is a planar surface area where the front surface of the substrate is in direct contact with the enclosure body 80, and the connection transition region 813 is an inclined surface area where the front surface of the substrate connects the enclosure contact region 812 and the functional region 811. In the example shown in FIG. 8-2, a portion of the connection transition region 813 is also in direct contact with the enclosure body 80, so that it may further extend the path between the enclosure contact region 812 and the functional region 811, and meanwhile improve the strength and the moisture resistance of the support.

Referring to FIG. 8-3 for another example, the enclosure contact region 812 is a planar surface area where the front surface of the substrate is in direct contact with the enclosure body 80, and the connection transition region 813 is an arc-shaped surface area where the front surface of the substrate connects the enclosure contact region 812 and the functional region 811. The arc-shaped surface area is a convex arc-shaped surface area protruding outward from the substrate 81. In the example shown in FIG. 8-3, a portion of the connection transition region 813 is also in direct contact with the enclosure body 80, so that it may further extend the path between the enclosure contact region 812 and the functional region 811 to improve the moisture resistance, and also enhance the strength of the support. Alternatively, in addition to the convex arc-shaped surface, the connection transition region 813 in the present embodiment may also be a concave arc-shaped surface that is recessed toward the inside of the substrate 81. FIG. 8-4 shows an example that the connection transition region 813 is a concave arc-shaped surface. It can extend the path between the enclosure contact region 812 and the functional region 811 to improve the moisture resistance, and meanwhile enhance the strength of the support.

In addition, it should be understood that, in the present embodiment, the connection transition regions 813 on the opposite sides of the front surface of the substrate may also be provided as the same type of surface, or different types of surfaces. For example, as shown in FIG. 8-5, the connection transition region 813 on one side of the substrate is provided as a convex arc-shaped surface, and the connection transition region 813 on the other side is provided as a concave arc-shaped surface. The specific arrangement may be flexibly adjusted according to the specific application scenario and the manufacturing process.

In the present embodiment, the connection transition region may also be a combined surface, wherein the combined surface includes, but not limited to a combination of at least two of a planar surface, an inclined surface, and an arc-shaped surface.

For example, as shown in FIG. 8-6, the enclosure contact region 812 is a planar surface area where the front surface of the substrate is in direct contact with the enclosure body 80, and the connection transition region 813 is a combined surface of an inclined surface and an arc-shaped surface that are configured for the front surface of the substrate connecting the enclosure contact region 812 and the functional region 811. Another example shown in FIG. 8-7 is different from the support shown in FIG. 8-6 in that the connection transition region 813 is formed by combining two inclined surfaces and a planar surface connecting the two inclined surfaces. Another example shown in FIG. 8-8 is different from the support shown in FIG. 8-6 and FIG. 8-7 in that the connection transition region 813 is formed by sequentially combining an inclined surface, a planar surface, and an arc-shaped surface. Therefore, the connection transition region 813 in the present embodiment may be a combined surface, and the specific type of combination can be flexibly adjusted. It should also be understood that the enclosure contact region 812 in the present embodiment may also be a combined surface, and the type of combination may be the same or different from that of the connection transition region 813.

In the present embodiment, a connection transition region is further provided between the enclosure contact region and the functional region on the substrate, which can further extend the path between the enclosure contact region 812 and the functional region 811 to improve the moisture resistance. Optionally, the connection transition region may also be at least partially in contact with the enclosure body, so that the contact area between the substrate and the enclosure body may be increased, and the strength of the support may be improved.

### Embodiment 7

In order to facilitate understanding, the present embodiment shows an example in which a connection transition region is provided between the enclosure contact region and the functional region on the substrate, and the functional region is located below the enclosure contact region.

In an example of the present embodiment, a plane where the functional regions of the positive electrode substrate and the negative electrode substrate are located is provided lower than a plane where the enclosure contact region is located.

In an example of the present embodiment, the functional regions of the positive electrode substrate and the negative electrode substrate are located at the bottom of the reflective cavity formed by the enclosure body. The height difference between the plane where the functional region is located and the plane where the enclosure contact region is located can be flexibly adjusted. For example, the height difference may set to be greater than zero, and less than or equal to a quarter of the depth of the reflection cavity formed by the enclosure contact region. Alternatively, the height difference may also be set to be other values as required, such as greater than zero and less than or equal to one-fifth, one-sixth, or one-third of the depth of the reflection cavity.

In the present embodiment, the connection transition region may be an inclined surface, an arc-shaped surface, or a combined surface, and the combined surface includes a combination of at least two of a planar surface, an inclined surface, and an arc-shaped surface.

Optionally, at least a portion of the connection transition region may also be in contact with the enclosure body to increase the contact area between the substrate and the enclosure body, thereby increasing the strength of the support.

In the present embodiment, the type of the enclosure contact region and type of the connection transition region may be the same or different, and/or the forming process for the enclosure contact region and the forming process for the connection transition region may be the same or different. It should also be understood that the enclosure contact region in the present embodiment may also be several types of surfaces as shown in Embodiment 2.

In FIGS. 9-1 to 9-9, 90 is an enclosure body, 91 is a substrate (it may be a positive electrode substrate and/or a negative electrode substrate), 911 is a functional region, 912 is an enclosure contact region, and 931 are insulating protrusions provided at both ends of an insulating spacer. It should be understood that the specific arrangement of the insulating protrusions can refer to the foregoing embodiments and is not limited to the present embodiment.

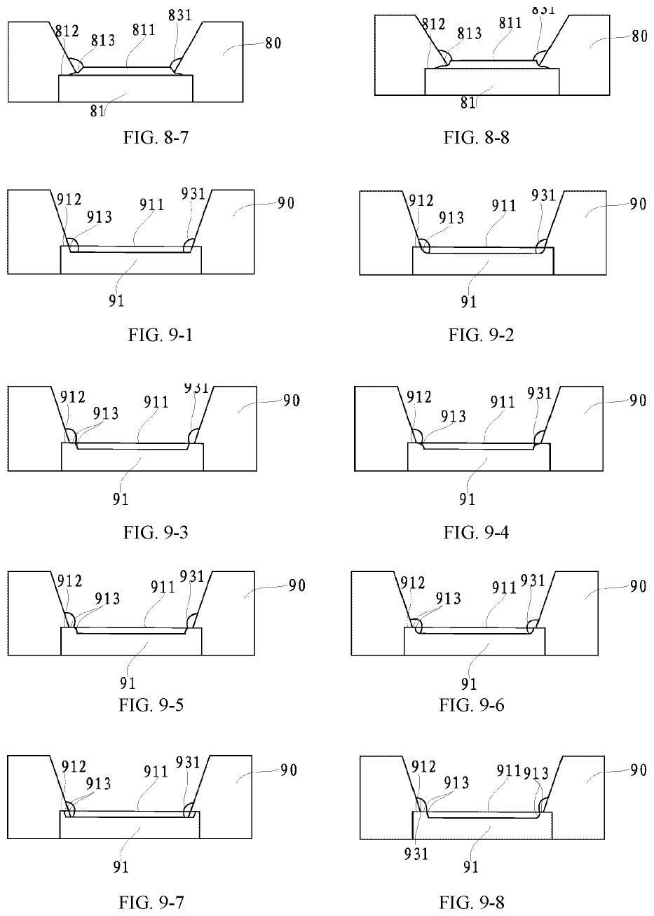

Referring to FIG. 9-1 for an example, the enclosure contact region 912 is a planar surface area where the front surface of the substrate is in direct contact with the enclosure body 90, and the connection transition region 913 is an inclined surface area connecting the enclosure contact region 912 and the functional region 911. Through the arrangement of the connection transition region 913, the path between the enclosure contact region 912 and the functional region 911 may be further extended, such that the moisture resistance of the support may be improved.

Referring to FIG. 9-2 for another example, the enclosure contact region 912 is a planar surface area where the front surface of the substrate is in direct contact with the enclosure body 90, and the connection transition region 913 is an arc-shaped surface area connecting the enclosure contact region 912 and the functional region 11. In the example shown in FIG. 9-2, the arc-shaped surface area is a concave arc-shaped surface area recessed toward the back side of the substrate 91. Compared with the inclined surface, the concave arc-shaped surface area of the connection transition region may further extend the path between enclosure contact region 912 and the functional region 911 to improve the moisture resistance and strength of the support. In the present embodiment, when the connection transition region 913 is an arc-shaped surface area connecting the enclosure contact region 912 and the functional region 11, it may also be a convex arc-shaped surface area protruding upward from the front surface of the substrate 91, as shown in FIG. 9-4. The opposite inclined surface of the connection transition region may also further extend the path between the enclosure contact region 912 and the functional region 911, and further improve the moisture resistance and strength of the support.

In the present embodiment, the connection transition region may also be a combined surface, and the combined surface may include, but not limited to, a combination of at least two of a planar surface, an inclined surface, and an arc-shaped surface.

Referring to FIG. 9-3 for another example, the enclosure contact region 912 is a planar surface area where the front surface of the substrate is in direct contact with the enclosure body 90, and the connection transition region 913 is a combined surface of a planar surface area and an inclined surface area that are configured for the front surface of the substrate connecting the enclosure contact region 912 and the functional region 911. The combined surface may further extend the path between the enclosure contact region 912 and the functional region 911 to improve the moisture resistance.

Referring to FIG. 9-5 for another example, the enclosure contact region 912 is a planar surface area where the front surface of the substrate is in direct contact with the enclosure body 90, and the connection transition region 913 is a combined surface of a planar surface and an arc-shaped surface that are configured for the front surface of the substrate connecting the enclosure contact region 912 and the functional region 911. The arc-shaped surface is a convex arc-shaped surface area protruding upward from the front surface of the substrate 91. Referring to FIG. 9-6 for another example, which differs from the support shown in FIG. 9-5 in that the connection transition region 913 is a combination of a planar surface and a concave arc-shaped surface area, and the combined surface may further extend the path between the enclosure contact region 912 and the functional region 911 to improve moisture resistance.

In addition, it should be understood that, in the present embodiment, the connection transition regions 913 on the opposite sides of the front surface of the substrate may also be provided as the same type of surface, or different types of surfaces. For example, as shown in FIG. 9-8, the connection transition region 913 on one side of the substrate is provided as a combined surface of a planar surface and an inclined surface, and the connection transition region 913 on the other side is a combined surface of a planar surface and a concave arc-shaped surface. The specific arrangement may be flexibly adjusted according to the specific application scenario and the manufacturing process.

In addition, in the present embodiment, a connection transition region is further provided between the enclosure contact region and the functional region on the substrate, and at least a portion of the connection transition region may be in direct contact with the enclosure contact region 912 to increase the contact area between the substrate and the enclosure body at the same time. For example, as shown in FIG. 9-7, a combined surface 913 which combines an inclined surface and a planar surface is completely in direct contact with the enclosure contact region 912, thereby further increasing the contact area between the substrate and the enclosure body, enhancing the strength and the air tightness of the support, and further improving the moisture resistance.

### Embodiment 8

The present embodiment provides an LED, which includes the LED support as shown in the above embodiments, and at least one LED chip disposed on a positive electrode substrate and/or a negative electrode substrate. A positive electrode lead and a negative electrode lead of the LED chip are electrically connected to the positive electrode substrate and the negative electrode substrate, respectively. It should be understood that the LED chip in the present embodiment may be a flip-chip LED chip or a formal LED chip. The ways for the positive and negative electrode leads electrically connecting with the positive and the negative electrode substrate, respectively, include, but not limited to, conductive wires, conductive adhesives, or other forms of conductive materials.

It should be understood that the colors of the LEDs provided by the present embodiment that are irradiated and presented to users can be flexibly adjusted according to actual needs and application scenarios. The color of the light emitted by the LED may be flexibly controlled by, but not limited to, the following factors: the color of the light emitted by the LED chip itself, whether the LED is equipped with a light conversion layer, and if yes, the type of light conversion layer.

In an example of the present embodiment, the LED may further include a lens gel layer or a diffusion gel layer disposed on the LED chip (or disposed on a light conversion gel layer if equipped with a light conversion gel layer).

It should be understood that, in an example, the light conversion gel layer may be a fluorescent gel layer containing a phosphor, or a colloid containing a quantum dot photoluminescence material, or other light conversion gels or films that can perform light conversion. It may also include diffusion powder or silicon powder as required. According to the present embodiment, the method of forming the light conversion gel layer, the lens gel layer or the diffusion gel layer on the LED chip includes, but is not limited to, dispensing, molding, spray coating, pasting, and the like.

For example, the light conversion gel layer may include a phosphor gel layer, a fluorescent film, or a quantum dot QD film. The phosphor gel layer and the fluorescent film may be made of inorganic phosphors, which may be inorganic phosphors doped with rare earth elements. Inorganic phosphors may include, but are not limited to, at least one of silicate, aluminate, phosphate, nitride, or fluoride phosphors.

For another example, the quantum dot QD film can be made of quantum dot phosphors. The quantum dot phosphors may include, but are not limited to, at least one of BaS, AgInS2, NaCl, Fe2O3, In2O3, InAs, InN, InP, CdS, CdSe, CdTe, ZnS, ZnSe, ZnTe, GaAs, GaN, GaS, GaSe, InGaAs, MgSe, MgS, MgTe, PbS, PbSe, PbTe, Cd(SxSe1-x), BaTiO3, PbZrO3, CsPbCl3, CsPbBr3, CsPbI3.

In the present embodiment, the type of light emitted by the LED chip itself may be visible light that is visible to the naked eyes, or ultraviolet light or infrared light that is invisible to the naked eyes. When the type of light emitted by the LED chip itself is ultraviolet light or infrared light that is invisible to the naked eyes, a light conversion layer may be disposed on the LED chip to convert the invisible light to visible light, such that the light emitted by the LED is visible to the user. For example, when the light emitted by the LED chip itself is ultraviolet light, and if the LED is supposed to present white light visible to the user, the light conversion layer may be made by mixing red, green, and blue phosphors.

The present embodiment provides a light-emitting device, which includes the LED exemplified in the foregoing embodiments. The light-emitting device in the present embodiment may be a lighting device, a light signal indicating device, a supplementary light device, or a backlight device, and the like. In particular as a lighting device, it may be a lighting device used in various fields, such as table lamps, fluorescent lamps, ceiling lamps, downlights, street lamps, projection lamps in daily life; high beams, low beams, ambient lights in automobiles; surgical lamps, low-electromagnetic lighting lamps in the medical field or the lights for various medical instruments; various color lamps, landscape lighting lamps, advertising lamps in the decorative field. In particular as a light signal indicating device, it may be a signal indicator lamp in the traffic field or a signal status indicator of a communication device in the communication field. As a supplementary light device, it may be a supplementary light in the photography field, such as a flash, a supplementary light, or a plant supplementary light that supplements light for plants in the agricultural field. As a backlight device, it may be a backlight module applied to various backlight fields, such as displays, televisions, and mobile terminals such as mobile phones, advertising players, and the like. It should be understood that the above-mentioned applications are merely a few applications exemplified for the present embodiment, and the application of the LED is not limited to the above-mentioned examples.

The above detailed description of the embodiments of the present invention in combination with specific implementations is intended merely for elaboration, and the embodiments of the present invention are not limited thereto. For people having ordinary skill in the art, simple deductions or substitutions that can be made without departing from the concept of the embodiments of the present invention should be regarded as falling within the protection scope of the present invention.

1. A LED support, comprising:
a positive electrode substrate, a negative electrode substrate, and an insulating spacer, wherein the insulating spacer is provided between the positive electrode substrate and the negative electrode substrate to insulate and separate the two;
the LED support further comprising an enclosure body enclosing the positive electrode substrate, the negative electrode substrate, and the insulating spacer, wherein the enclosure body is an insulating enclosure body;
a functional region and an enclosure contact region contacting the enclosure body are included on a front surface of each of the positive electrode substrate and the negative electrode substrate, wherein the functional region and the enclosure con tact region of at least one of the positive electrode substrate and the negative electrode substrate are not on the same plane.

2. The LED support according to claim 1, wherein the functional region and the enclosure contact region of the positive electrode substrate are not on the same plane, and the functional region and the enclosure contact region of the negative electrode substrate are not on the same plane, neither.

3. The LED support according to claim 1, wherein the enclosure contact region is directly connected to the functional region.

4. The LED support according to claim 1, wherein a connection transition region is further provided between the functional region and the enclosure contact region of at least one of the positive electrode substrate and the negative electrode substrate.

5. The LED support according to claim 4, wherein the connection transition region is an inclined surface, an arc-shaped surface, or a combined surface, wherein the combined surface includes a combination of at least two of a planar surface, an inclined surface, and an arc-shaped surface.

6. The LED support according to claim 1, wherein a plane where the functional region is located is higher than a plane where the enclosure contact region is located.

7. The LED support according to claim 1, wherein a plane where the functional region is located is lower than a plane where the enclosure contact region is located.

8. The LED support according to claim 1, wherein a height difference between a plane where the functional region is located and a plane where the enclosure contact region is located is greater than zero and less than or equal to a quarter of a depth of a reflection cavity formed by the enclosure body.

9. The LED support according to claim 1, wherein at least one end of a front surface of the insulating spacer is provided with an insulating protrusion.

10. The LED support according to claim 9, wherein two ends of the front surface of the insulating spacer are provided with insulating protrusions.

11. The LED support according to claim 9, wherein the insulating protrusion spans the front surface of the positive electrode substrate and/or the front surface of the negative electrode substrate.

12. The LED support according to claim 9, wherein the functional regions of the positive electrode substrate and the negative electrode substrate are located at a bottom of the reflection cavity formed by the enclosure body, wherein the insulating protrusion is in direct contact with an inner side surface of the reflection cavity, and a height of the insulating protrusion is less than a height of the inner side surface of the reflection cavity formed by the enclosure body.

13. The LED support according to claim 9, wherein the insulating protrusion is integrally formed with the insulating spacer, and/or the insulating protrusion and the insulating spacer are made of the same material.

14. The LED support according to claim 9, wherein a profile of a longitudinal cross-section of the insulating protrusion along a height direction is an arc-shaped profile, or a profile formed by an upper horizontal side, a lower horizontal side, and an arc shape located between the upper horizontal side and the lower horizontal side.

15. The LED support according to claim 1, wherein two opposite long sides of a lateral cross-section profile of the insulating spacer are arc-shaped sides, or curved sides having at least one curved edge, or bended sides having at least one bended edge, or inclined sides having an included angle greater than or equal to 10° and less than 90° with a short side of the negative electrode substrate.

16. The LED support according to claim 15, wherein the two opposite long sides of the lateral cross-section profile of the insulating spacer are parallel to each other.

17. An LED, comprising the LED support according to c1aim 1 and at least one LED chip disposed on the positive electrode substrate and/or the negative electrode substrate, wherein a positive electrode lead and a negative electrode lead of the LED chip are electrically connected to the positive electrode substrate and the negative electrode substrate, respectively.

18. A light-emitting device, comprising the LED according to claim 17, wherein the light-emitting device is a lighting device, a light signal indicating device, a supplementary light device, or a backlight device.

19. The LED support according to claim 4, wherein the functional regions of the positive electrode substrate and the negative electrode substrate are located at a bottom of a reflection cavity formed by the enclosure body, an inner side surface of the reflection cavity is provided with an insulating protrusion, and the insulating protrusion contacts the front surface of the positive electrode substrate or the negative electrode substrate in the connection transition region.

20. The LED support according to claim 1, wherein a width of one end of the insulating spacer is different from a width of another end of the insulating spacer.
